(19) United States
(12) Patent Application Publication
(10) Pub. No.: US 2011/0175492 A1
(43) Pub. Date: Jul. 21, 2011

(54) Temperature Compensation Device and Method for MEMS Resonator

(75) Inventors: Steve Stoffels, Heverlee (BE); Hendrikus Tilmans, Maasmechelen (BE)

(73) Assignee: IMEC, Leuven (BE)

(21) Appl. No.: 13/009,638

(22) Filed: Jan. 19, 2011

Related U.S. Application Data
(60) Provisional application No. 61/297,009, filed on Jan. 21, 2010.

(51) Int. Cl. H03H 9/08

(52) U.S. Cl. 310/343

(57) ABSTRACT

The present disclosure provides a device including a MEMS resonating element, provided for resonating at a predetermined resonance frequency, the MEMS resonating element having at least one temperature dependent characteristic, a heating circuit arranged for heating the MEMS resonating element to an offset temperature (T_{offset}), a sensing circuit associated with the MEMS resonating element and provided for sensing its temperature dependent characteristic, and a control circuit connected to the sensing circuit for receiving measurement signals indicative of the sensed temperature dependent characteristic and connected to the heating circuit for supplying a control signal thereto to maintain the temperature of the MEMS resonating element at the offset temperature. The heating circuit includes a tunable thermal radiation source and the MEMS resonating element is provided so as to absorb at least a portion of the thermal radiation generated by the tunable thermal radiation source.

### CROSS-REFERENCE TO RELATED APPLICATIONS

The present application claims priority to U.S. Provisional Patent Application Ser. No. 61/297,009, filed in the United States Patent and Trademark Office on Jan. 21, 2010, the entire contents of which is incorporated herein by reference.

### BACKGROUND

1. Field of the Invention

The present disclosure relates to a device and a method for compensating the temperature in a MEMS resonator.

2. Description of the Related Art

Micro-electromechanical systems (MEMS) resonators can be used as accurate timing references, to replace, for example, quartz crystals in timing circuits as disclosed by W. T. Hsu, J. R. Clark, et al., in “Mechanically temperature-compensated flexural-mode micromechanical resonators,” Technical Digest International Electron Devices Meeting 2000 (IEDM2000), pp. 399-402, hereby incorporated by reference in its entirety. One of the drawbacks of these MEMS resonators is the resonant frequency drift with respect to temperature and aging. Typical values for frequency drift with respect to temperature are several tens to hundreds of ppm/° C., depending on the structural material(s) constituting the MEMS resonator (e.g. Si, Si—SiO2). Quartz crystals, on the other hand, have a temperature stability of 1 ppm/° C. or lower (see FIG. 1: quartz crystal (AT-cut, tuning fork), Si-MEMS crystal, Si—SiO2 MEMS crystal). For MEMS resonators to become a viable alternative to quartz crystals, they will have to reach comparable temperature stabilities.

Temperature compensation of the resonance frequency, i.e. the control of thermally induced frequency variations, is mostly achieved using electrical techniques, in which a controlled voltage or current provides frequency tuning. These techniques are also used in the following background documents.

Several solutions addressing the issue of temperature compensation are known. U.S. Pat. No. 6,987,432 discloses active and passive solutions. An active solution comprises determining the actual operating frequency for a beam resonator in relation to a desired resonance frequency, and thereafter applying a compensating stiffness to the resonator to maintain the desired resonance frequency. A passive solution for frequency stabilization with temperature of a MEMS resonator results from specific steps during the method of fabricating a micromechanical resonator, so that the working gap between the beam and the electrode adjusts itself with temperature to vary a compensating stiffness applied to the beam.

U.S. Pat. No. 7,427,905 discloses a temperature controlled MEMS resonator and a method for controlling resonator frequency by providing an electrical current to the beam structure and thereby heating the beam structure.

### SUMMARY

As used herein, the term “offset temperature” refers to a temperature substantially above ambient temperature, such that an element heated to the offset temperature by means of a heat source can be cooled by switching off or reducing the heat source.

As used herein, the term “MEMS resonating element” refers to a micro-electromechanical systems element that is arranged for resonating at a predetermined resonance frequency (or in multiple modes) in response to any given source of energy causing its resonation, such as for example a beam suspended above a substrate by means of tethers between a pair of electrodes upon which a suitable bias can be applied.

As used herein, the term “temperature dependent characteristic” refers to at least one physical, mechanical, or electrical parameter of the MEMS resonating element having a thermal coefficient whose value is dependent on the operating temperature of the MEMS element. This parameter can be, for example, the resonance frequency of the MEMS element, the resistance of the MEMS element, the thermal radiation of the MEMS element, or any other temperature dependent parameter.

The disclosure provides a device comprising: a MEMS resonating element, provided for resonating at a predetermined resonance frequency, the MEMS resonating element having a temperature dependent characteristic; a heating means, arranged for heating the MEMS resonating element to an offset temperature (T_{offset}); a sensing means, associated with the MEMS resonating element and provided for sensing its temperature dependent characteristic; a control circuit connected to the sensing means for receiving measurement signals indicative of the sensed temperature dependent characteristic and connected to the heating means for supplying a control signal thereto, for maintaining the temperature of the MEMS resonating element at the offset temperature. According to the disclosure, the heating means comprises a tunable thermal radiation source and the MEMS resonating element is provided for absorbing thermal radiation generated by the tunable thermal radiation source.

In other words, the MEMS resonating element is arranged for receiving thermal radiation emitted by the tunable thermal radiation source while the control circuit is arranged for monitoring a variation in at least one temperature dependent parameter of the MEMS resonating element. Upon absorbing this thermal energy the resonator is heated and the value of the at least one temperature dependent parameter changes. A shift in this parameter value is monitored by the control circuit, which adapts its output signal to the tunable thermal radiation source, for changing the amount of the emitted thermal radiation in relation to the monitored parameter value shift. This can be done by changing the intensity of the emitted thermal radiation, by switching the source on/off intermittently, or otherwise. The MEMS resonating element absorbs the controlled thermal radiation emitted by the tunable thermal source, as a result of which the MEMS element is brought to the operating temperature/point (e.g., the temperate at which the temperature dependent characteristic is at a desired parameter value).

By providing thermal energy in the form of thermal radiation, the thermal energy can be focused towards the MEMS resonating element, thereby reducing or even avoiding directly heating the surroundings of the MEMS resonating element. As the thermal energy can be more directly absorbed by the MEMS resonating element, a much higher reaction speed to temperature variations can be achieved compared to prior devices.

In an embodiment, the MEMS resonating element may be fabricated in a material having a low thermal conductivity, such as, for example, silicon-germanium (SiGe), metals, permalloy, vanadium oxide, or (poly-crystalline) silicon. SiGe is a material having low thermal conductivity, allowing the effective confinement of the absorbed thermal radiation to the resonator itself and reducing a loss of thermal energy. This makes it possible to use higher operational temperatures. A typical operation interval ranges from −20° C. up to 90° C. The energy confinement may increase the range over which the temperature dependent parameter(s) of the MEMS resonating element can be tuned as a function of the operating temperature, as a higher temperature increase equals a higher parameter shift.

In an embodiment, the MEMS resonating element is suspended above a substrate by means of tethers having a high thermal resistance (preferably at least an order higher than that of the MEMS resonating element), i.e. made of a material having low thermal conductivity (e.g. SiGe), a small cross-sectional area (compared to that of the MEMS resonating element), and/or a long length.

In an embodiment, the control circuit may further comprise a temperature sensor, placed in the proximity of the MEMS resonating element, to measure the operating temperature of the MEMS resonating element. The control circuit, in response to temperature data measured by the temperature sensor, may provide the control information using a mathematical relationship or data contained in a look-up table, to generate the appropriate output signal to a thermal radiation source. This adds a temperature compensation on top of the feedback loop that uses the temperature dependent parameter(s) of the MEMS resonating element, by which accuracy can be enhanced.

In an embodiment, the control circuit comprises a comparator for comparing the measured value of the temperature dependent parameter, to a reference value thereof. From this comparison the relative shift of the effective parameter value towards the reference value can be determined. The reference value may be generated externally for example when the measured parameter is frequency. The reference may also be generated internally in the device. For example, when the measured parameter is a frequency, the device may comprise a second calibrated resonator for providing a reference frequency, referred to as a calibrated frequency, to the comparator of the control circuitry.

In an embodiment, the tuneable thermal radiation source is a light source. This light source can be an LED, whose intensity can be adjusted by controlling the LED current supplied to the LED.

In an embodiment, the tunable thermal radiation source further comprises an optical waveguide for guiding the thermal radiation towards the MEMS resonating element. The wavelength of the tunable thermal radiation source can be selected such that there is a maximum absorption of the thermal energy by the MEMS resonating element. By selecting the wavelength for maximal absorption by the material(s) constituting the MEMS resonating element, absorption by other materials can be reduced thereby resulting in a more efficient use of the radiated thermal energy.

In an embodiment, the device is made of CMOS compatible materials. In particular the MEMS resonating element may be fabricated in a material having a low thermal conductivity such as silicon-germanium (SiGe) and/or SiO2.

In an embodiment, the MEMS resonating element is manufactured on a first substrate while the tunable thermal radiation source is manufactured on a second substrate, such as, for example, a capping wafer. This second substrate can be flip chipped onto the first substrate containing the MEMS resonating element such that the thermal radiation source is facing the MEMS resonating element. The stack of first and second substrates thereby forms a closed environment, i.e. a package, for the MEMS resonating element and the thermal radiation source.

### BRIEF DESCRIPTION OF THE SEVERAL VIEWS OF THE DRAWINGS

The disclosure will be further elucidated by means of the following description and the appended figures.

FIG. 1 shows a comparison of the resonance frequency drift of resonators composed of different materials.

FIG. 2 shows an embodiment of a device according to the disclosure.

FIG. 3 shows a schematic drawing of a bulk acoustic longitudinal resonator which can be used in embodiments of the disclosure.

FIG. 4 shows measurement data for a 100×100 μm SiGe resonator showing the frequency change versus the incident light power on the resonator, according to an embodiment of the disclosure.

FIG. 5 shows the resonator temperature vs. stabilization time illustrating the fast response time of a resonator element to incident light power, according to an embodiment of the disclosure.

### DETAILED DESCRIPTION

The present disclosure will be described with respect to particular embodiments and with reference to certain drawings but the disclosure is not limited thereto but only by the claims. The attached Figures are only schematic drawings and are non-limiting. In the drawings, the size of some of the elements may be exaggerated and not drawn to scale, for illustrative purposes. The dimensions and the relative dimensions do not necessarily correspond to actual reductions to practice of the disclosure.

Furthermore, the terms first, second, third, and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Moreover, the terms top, bottom, over, under, and the like in the description and the claims are used for descriptive purposes and not necessarily for describing relative positions. The terms so used are interchangeable under appropriate circumstances and the embodiments of the disclosure described herein can operate in other orientations than described or illustrated herein.

The term “comprising,” used in the claims, should not be interpreted as being restricted to the means listed thereafter; it does not exclude other elements or steps. It needs to be interpreted as specifying the presence of the stated features, integers, steps, or components as referred to, but does not preclude the presence or addition of one or more other features, integers, steps, or components, or groups thereof. Thus, the scope of the expression “a device comprising components A and B” should not be limited to devices consisting only of components A and B. It means that with respect to the present disclosure, the only relevant components of the device are A and B.

It is an aim of the present disclosure to provide an alternative temperature stabilized MEMS resonator and an alternative method for temperature stabilizing a MEMS resonator.

This aim is achieved according to the disclosure as defined in the independent claims.

As mentioned in the Background section, several temperature compensation approaches have been provided. In the following these are listed and compared.

Voltage compensation. It is well established that, for electrostatically actuated resonators, applying a bias voltage over the actuation electrodes of a MEMS resonator introduces an electrostatic spring softening effect, causing a lowering of the resonance frequency with an applied bias voltage. However for very stiff modes, e.g. high frequency bulk-acoustic longitudinal modes, the effect a bias voltage has on resonant frequency is very small. Rather high bias voltages (e.g., >50 Vdc) are required to induce a noticeable frequency shift. Therefore, for these stiff modes, only a very small shift can be expected with respect to the applied voltage.

Mechanical compensation. Heating up the resonator results in thermally-induced stresses and/or strains in the structural material. These stresses and/or strains may, depending on the design, lead to a shift of the resonant frequency. Therefore, this effect can be used as a compensation technique, i.e., the mechanical structure is designed in such a way that the thermal stresses and/or strains cause a frequency shift which is opposite to the frequency shift due to temperature variation. Typically, however, this requires quite specific designs that undesirably increase the complexity of the structure. Furthermore, a configuration as in W. T. Hsu, J. R. Clark, et al., “Mechanically temperature-compensated flexural-mode micromechanical resonators,” Technical Digest International Electron Devices Meeting 2000 (IEDM2000), pp. 399-402, employs unfocused or non-specific heating of the entire micromechanical resonator (leading to uncertainty regarding the resonator temperature).

Vis-à-vis these known techniques, the disclosure offers the following advantages. Devices according to the disclosure are insensitive to the stiffness of the resonator. The frequency shift due to temperature variations is a certain percentage of the resonance frequency; this percentage only depends on the material properties and is independent of stiffness or design of the resonator. It is noted that the temperature increase with respect to the incident light power, is dependent on the design. Further, by providing thermal energy in the form of thermal radiation, the thermal energy can be focused towards the MEMS resonating element thereby reducing or even avoiding directly heating the surroundings of the MEMS resonating element. As the thermal energy can be more directly absorbed by the MEMS resonating element, a much higher reaction speed of the device of the disclosure to temperature variations can be achieved compared to prior devices.

In the example that follows, a bar resonator 20 is used as a MEMS resonating element. The disclosure is, however, not limited to resonant beams having rectangular cross sections. Further, the disclosure is directed to a temperature compensated micro-electromechanical resonator as well as controlling micro-electromechanical resonators having mechanical structures that include integrated heating and/or temperature sensing elements. The disclosure may further be applied in combination with the above mentioned techniques of voltage compensation and mechanical compensation, if desired.

There is a need for an efficient compensation technique for stability of MEMS resonators, in particular the resonance frequency, over a temperature operating range, which overcomes some or all of the shortcomings of prior resonators.

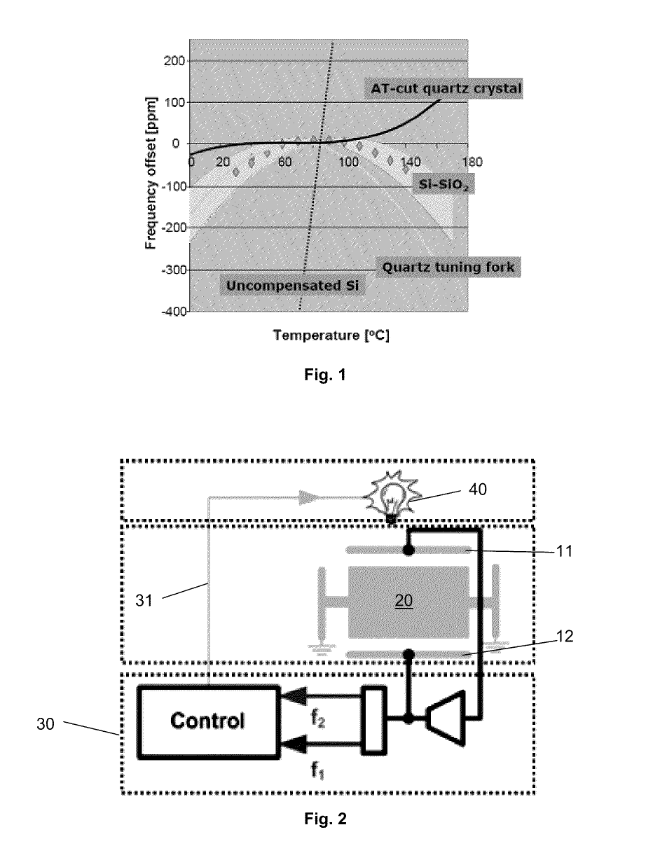

The proposed device for achieving higher temperature stability is shown schematically in FIG. 2 and comprises a resonator 20 connected to a control circuit 30 and a controlled thermal radiation source 40. In this device, changes in a temperature dependent parameter, e.g. the resonance frequency, are detected by the control circuit 30, which in turn controls the thermal energy emitted by the thermal radiation source 40 (e.g. a light source such as an integrated LED). As can be seen in FIG. 2, there is a feedback loop between the thermal radiation source 40, the resonator element 20 absorbing this thermal radiation, the control circuit 30 monitoring the temperature dependent parameter of this resonator element 20, and the control circuit 30 controlling the thermal radiation radiated by the thermal radiation source 40.

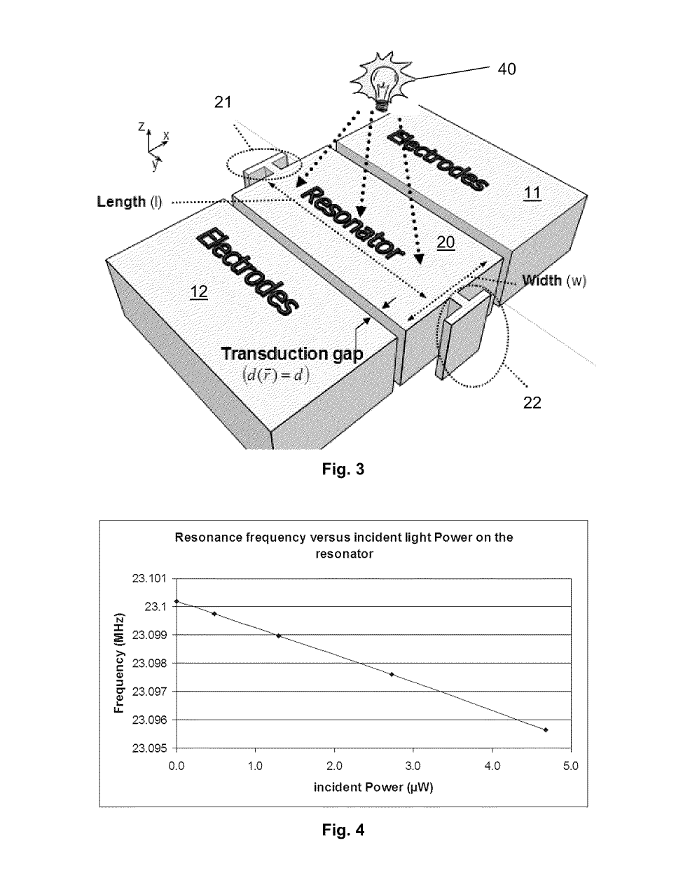

FIG. 3 shows the bar resonator element in more detail. The bar resonator 20 is suspended between a pair of electrodes 11, 12. The first electrode 11 is used for applying a bias for causing the resonator element 20 to resonate at a predetermined frequency. The second electrode 12 is used for sensing the resonance frequency of the resonator element 20. Since the Young's modulus (E) of the resonating material is dependent on its temperature, a change in temperature of the resonator causes a change in the Young's modulus, which directly translates into a resonant frequency shift (as roughly speaking the resonant frequency is proportional to \sqrt{E}).

In another embodiment, resistive sensing may be used, measuring changes in resistance with temperature. This can, for example, be done by supplying a current through the resonator or part thereof and measuring the voltage (or by putting a voltage over the resonator or part thereof and measuring the current). According to this measured voltage, which is indicative of resistance shift, the intensity of the thermal radiation source can be adapted via the control circuit. When thermal energy falls onto the resonator, it is absorbed by the material of the resonator and causes an increase of the temperature of the resonating element and the resistance changes. Since the electrical resistance (ρ) of the resonating material is dependent on the temperature, a change in temperature of the resonator causes a change in the resistance, which directly translate into a change of a current passing through the resonator.

The resonator 20 is preferably fabricated in a material having a low thermal conductivity, such as, for example, silicon-germanium (SiGe) based technology. SiGe is a material with low thermal conductivity, allowing for focused absorption. This is an advantage over prior thermal compensation techniques, wherein the heat source heats both the resonator and its surroundings. For SiGe, thermal radiation is preferably used at a wavelength in the range from 500-1100 nm.

The heat is furthermore confined to the resonator 20 by suspending it by means of tethers 21, 22 having a high thermal resistance, i.e. made of a material having low thermal conductivity (e.g. SiGe) and/or a small cross-sectional area (compared to that of the MEMS resonating element, e.g. 1% or less) and/or a long length. In general, the smaller the cross sectional area of the tether and the longer the length of the tether, the better, but there is a tradeoff against mechanical stability. There is some liberty in selecting the length, especially in the case of T-shaped tethers where one of the arms of the T can be made relatively long while only minimally impacting the lateral mechanical stability.

The device of FIG. 2 is operated as follows. The resonator 20 is first heated to an offset temperature T_{offset} with the thermal radiation source. Once T_{offset} has been reached, the control circuit 30 is used to modulate the intensity of the thermal radiation source 40 in response to changes in the resonance frequency, thereby influencing the temperature of the resonator 20 to be maintained at T_{offset}. An example of a control circuit could be a comparator, comparing the measured resonance frequency f₁ and a reference frequency source f₂ and giving an output signal proportional to the difference between the frequencies. Tuning the control circuit such that changes in the resonance frequency are compensated by changes in T_{offset} can achieve a desired frequency stabilization. FIG. 4 shows the measured resonance frequency drift of a SiGe resonator in response to an external light source. Such data could be used for tuning the control circuit to the desired accuracy.

The reference f₂ of FIG. 2 could be data stored in a digital lookup table or could be implemented by means of an analog circuit (since the temperature dependence is usually linear of the range of interest). The reference f₂ of FIG. 2 could also be an overtone of the resonator, as the absolute shift in frequency with temperature is higher for the overtone. In particular, one could calibrate for the difference between the frequency of interest and the overtone, and use the absolute shift as a metric for the temperature change.

In the alternative, where electrical resistance is used as the temperature dependent parameter, the device is operated as follows. The resonator 20 is first heated to an offset temperature T_{offset} with the thermal radiation source 40. Once T_{offset} has been reached, the control circuit 30 is used to modulate the intensity of the thermal radiation source 40 (and therefore T_{offset}) in response to changes in the electrical resistance. An example of a control circuit could be a comparator, comparing the measured resistance value R₁ and a reference resistance value R₂ and giving an output signal proportional to the difference between the resistance values. Tuning the control circuit such that changes in the resistance values are compensated by changes in T_{offset} can achieve a desired resistance stabilization.

The measured resistance value R₁ and the reference resistance value R₂ can be AC, resp. DC voltages when an AC, resp. DC current source is used for sensing or AC, resp. DC currents when an AC, resp. DC voltage source is used for sensing. The currents/voltages may be continuous signals or intermitted signals.

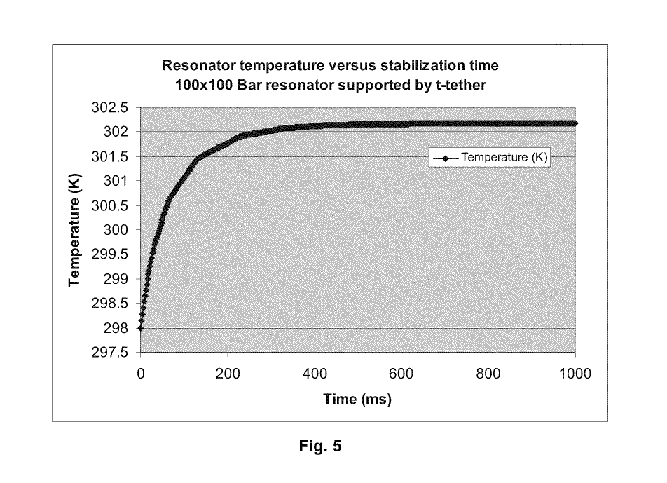

FIG. 5 shows the resonator temperature vs. stabilization time illustrating the fast response time of a resonator element according to an embodiment of the disclosure. From this data one can conclude that the fast response time provides for swift correcting shifts in the resonance frequency caused by absorbed thermal energy.

What is claimed is:

1. A device comprising:
a micro-electromechanical systems (MEMS) resonating element configured to resonate at a predetermined resonance frequency, the MEMS resonating element having at least one temperature dependent characteristic;
a heating circuit configured to heat the MEMS resonating element to an offset temperature (T_{offset});
a sensing circuit associated with the MEMS resonating element and configured to sense the temperature dependent characteristic; and
a control circuit, coupled to the sensing circuit and configured to receive measurement signals indicative of the sensed temperature dependent characteristic, and coupled to the heating circuit and configured to supply a control signal to the heating circuit to maintain the temperature of the MEMS resonating element at substantially the offset temperature T_{offset};
wherein the heating circuit comprises a tunable thermal radiation source and wherein the MEMS resonating element is disposed so as to absorb at least a portion of the thermal radiation generated by the tunable thermal radiation source.

2. The device according to claim 1, wherein the MEMS resonating element is formed in a material having a low thermal conductivity.

3. The device according to claim 1, wherein the MEMS resonating element is formed in silicon-germanium (SiGe).

4. The device according to claim 1, wherein the MEMS resonating element is suspended above a substrate by tethers having a high thermal resistance.

5. The device according to claim 1, further comprising a temperature sensor, disposed in proximity to the MEMS resonating element, configured to measure an operating temperature of the MEMS resonating element and provide corresponding temperature data to the control circuit.

6. The device according to claim 1, wherein the control circuit comprises a comparator for comparing the measurement signals indicative of the sensed temperature dependent characteristic to a reference value thereof.

7. The device according to claim 1, wherein the tuneable thermal radiation source is a light-emitting diode (LED), the control circuit being adapted for controlling an LED current supplied to the LED.

8. The device according to claim 1, wherein the tunable thermal radiation source comprises an optical waveguide for guiding the thermal radiation towards the MEMS resonating element.

9. The device according to claim 1, wherein the temperature dependent characteristic is the resonance frequency of the MEMS resonating element.

10. The device according to claim 1, wherein the temperature dependent characteristic is an electrical resistance of the MEMS resonating element.

11. The device according to claim 10, wherein sensing the temperature dependent characteristic comprises measuring the electrical resistance of the MEMS resonating element.

12. The device according to claim 1, wherein the device is composed of CMOS compatible materials.

13. The device according to claim 1, wherein the MEMS resonating element is provided over a first substrate and the tunable thermal radiation source is provided over a second substrate, the second substrate being flip chipped onto the first substrate such that the thermal radiation source is facing the MEMS resonating element and the stack of first and second substrates forms a closed environment for the MEMS resonating element and the thermal radiation source.

14. A method for controlling a device comprising a MEMS resonating element, provided for resonating at a predetermined resonance frequency and having at least one temperature dependent characteristic, the method comprising:
heating the MEMS resonating element to an offset temperature (T_{offset}) by means of a heating circuit;
sensing the temperature dependent characteristic by means of a sensing circuit associated with the MEMS resonating element; and
receiving measurement signals indicative of the sensed temperature dependent characteristic in a control circuit and thereupon generating a control signal for controlling the heating circuit to maintain the temperature of the MEMS resonating element at substantially the offset temperature T_{offset};
wherein a tunable thermal radiation source is used as the heating circuit and generates thermal radiation at least a portion of which is absorbed by the MEMS resonating element.

15. The method according to claim 14, wherein the method further comprises measuring an operating temperature of the MEMS resonating element by means of a temperature sensor, placed in proximity of the MEMS resonating element, and providing corresponding temperature data to the control circuit.

16. The method according to claim 14, wherein the method comprises comparing the measurement signals indicative of the sensed temperature dependent characteristic to a reference value thereof, and correspondingly generating the control signal.

17. The method according to claim 14, wherein the tuneable thermal radiation source is a LED and the step of controlling the heating means comprises controlling a light-emitting diode (LED) current supplied to the LED.

18. The method according to claim 14, wherein the thermal radiation is guided towards the MEMS resonating element by means of an optical waveguide.

19. The method according to claim 14, wherein sensing the temperature dependent characteristic comprises measuring the resonance frequency of the MEMS resonating element.

20. The method according to claim 14, wherein sensing the temperature dependent characteristic comprises measuring an electrical resistance of the MEMS resonating element.
